(19) United States
(12) Patent Application Publication
(10) Pub. No.: US 2025/0201588 A1
(43) Pub. Date: Jun. 19, 2025

(54) APPARATUS AND METHOD FOR TREATING SUBSTRATE

(71) Applicant: SAMSUNG ELECTRONICS CO., LTD., SUWON-SI (KR)

(72) Inventors: Dae-Woong CHOI, Suwon-si (KR); Hyun-Chul KIM, Suwon-si (KR); Hyun Mo KANG, Suwon-si (KR); Oh Chel KWON, Suwon-si (KR); Jin Hong PARK, Suwon-si (KR)

(21) Appl. No.: 18/910,677

(22) Filed: Oct. 9, 2024

(30) Foreign Application Priority Data
Dec. 18, 2023 (KR) 10-2023-0184898

(51) Int. Cl. H01L 21/67; H01L 21/02

(52) U.S. Cl. CPC H01L 21/67034; H01L 21/02052

(57) ABSTRACT

Apparatus and Method for treating substrate, are provided. A substrate treatment apparatus includes an upper body, a lower body coupled to the upper body and defining a substrate treating space therebetween, a seal disposed between the upper body and the lower body, wherein the seal seals the substrate treating space from an outside, a fluid supply unit configured to supply fluid to the substrate treating space and a controller. The fluid supply unit includes a first auxiliary fluid supply unit configured to control the fluid to flow at a first flow rate and a second auxiliary fluid supply unit configured to the fluid to flow at a second flow rate different from the first flow rate. The controller is configured to control the first auxiliary fluid supply unit and the second auxiliary fluid supply unit such that the fluid flows into the substrate treatment space through the first auxiliary fluid supply unit and the second auxiliary fluid supply unit in an ultra-high-speed pressurizing step, during at least one time interval.

### CROSS-REFERENCE TO RELATED APPLICATION

This application claims priority under 35 U.S.C. § 119 to Korean Patent Application No. 10-2023-0184898, filed on Dec. 18, 2023 in the Korean Intellectual Property Office, the contents of which in its entirety are herein incorporated by reference.

### 1. TECHNICAL FIELD

The present disclosure relates to a substrate and, more specifically, to an apparatus and method for treating a substrate.

### 2. DISCUSSION OF THE RELATED ART

To manufacture a semiconductor device, various processes such as deposition, photography, etching, cleaning, etc. are performed.

Generally, the cleaning process involves treating the substrate with chemicals and a rinse solution and then drying the same. The dry treatment step involves drying the rinse solution remaining on the substrate. The substrate is subjected to dry treatment with an organic solvent such as isopropyl alcohol (IPA). However, as a distance (CD: Critical Dimension) between patterns formed in the substrate becomes smaller, the organic solvent remains in a space between the patterns.

Recently, a supercritical treatment process is performed to remove the organic solvent remaining on the substrate. The supercritical treatment process is carried out in a space sealed from an outside to satisfy a specific condition of a supercritical fluid.

In order to create a sealed environment in a process chamber, it is important to use a seal such as an O-ring. When the O-ring is deformed or damaged, the sealed environment of the process chamber cannot be maintained and may lead to a defect in a substrate treating process.

### SUMMARY

According to an aspect of the present disclosure, there is provided a substrate treatment apparatus including an upper body, a lower body coupled to the upper body and defining a substrate treating space therebetween, a seal disposed between the upper body and the lower body, wherein the seal seals the substrate treating space from an outside, a fluid supply unit configured to supply fluid to the substrate treating space and a controller. The fluid supply unit includes a first auxiliary fluid supply unit configured to control the fluid to flow at a first flow rate and a second auxiliary fluid supply unit configured to the fluid to flow at a second flow rate different from the first flow rate. The controller is configured to control the first auxiliary fluid supply unit and the second auxiliary fluid supply unit such that the fluid flows into the substrate treatment space through the first auxiliary fluid supply unit and the second auxiliary fluid supply unit in an ultra-high-speed pressurizing step, during at least one time interval.

According to another aspect of the present disclosure, there is provided a substrate treatment method including moving a lower body so as to contact the upper body under an operation of a cylinder to define a substrate treating space therebetween, inserting both opposing side surfaces of each of the upper body and the lower body into a clamping space of a clamping unit and fixing the upper body and the lower body using the clamping unit and performing an ultra-high speed pressurizing step in which both a first auxiliary fluid supply unit and a second auxiliary fluid supply unit are opened so that fluid flows into the substrate treating space. Each of the first auxiliary fluid supply unit and the second auxiliary fluid supply unit is connected to the upper body and the lower body. The second auxiliary fluid supply unit controls the fluid to flow at a higher flow rate than a flow rate at which the first auxiliary fluid supply unit controls the fluid to flow. A pressure of the fluid flowing into the substrate treating space acts on the seal to deform a contact surface of the seal subjected to the pressure such that the substrate treating space is sealed from an outside by the deformed seal.

According to another aspect of the present disclosure, there is provided a substrate treatment apparatus including an upper body, a lower body coupled to the upper body to define a substrate treating space therebetween, a seal disposed between the upper body and the lower body and sealing the substrate treating space from an outside, a fluid supply unit configured to supply fluid to the substrate treating space, a clamping unit including a clamping space into which both opposing side surfaces of each of the upper body and the lower body are inserted and a controller. The fluid supply unit includes a first auxiliary fluid supply unit configured to control the fluid to flow at a first flow rate and a second auxiliary fluid supply unit configured to the fluid to flow at a second flow rate different from the first flow rate. In an ultra-high-speed pressurizing step, the controller is configured to open the first auxiliary fluid supply unit, and the controller is configured to open the second auxiliary fluid supply unit so that the fluid flows into the substrate treating space through the first auxiliary fluid supply unit and the second auxiliary fluid supply unit after a first time elapses.

### BRIEF DESCRIPTION OF DRAWINGS

The above and other aspects and features of the present disclosure will become more apparent by describing in detail some embodiments thereof with reference to the attached drawings, in which:

FIG. 1 is a plan view schematically showing a substrate treating apparatus according to some embodiments.

FIG. 2 and FIG. 3 are cross-sectional views schematically showing a substrate treating apparatus according to some embodiments.

FIG. 4 is a cross-sectional view schematically showing a supercritical fluid treating chamber according to some embodiments.

FIG. 5 is a diagram showing the fluid supply unit as shown in FIG. 2.

FIG. 6 is a perspective view showing the substrate support unit as shown in FIG. 2.

FIG. 7 is a perspective view showing the seal as shown in FIG. 2.

FIG. 8 is a diagram showing an operation sequence of the substrate treating apparatus according to some embodiments.

FIG. 9 is a flowchart for illustrating a replacement method of the seal.

FIG. 10 is a diagram illustrating an operation of the fluid supply unit in FIG. 5 according to some embodiments.

FIGS. 11, 12 and 13 are enlarged views of a S area of FIG. 2.

FIG. 14 is a cross-sectional view showing a seal according to some embodiments.

FIGS. 15, 16, 17 and 18 are diagrams for illustrating an operation of the fluid supply unit in FIG. 5 according to some embodiments.

FIG. 19 is a diagram illustrating example pressure change inside a chamber while performing an operation using the supercritical fluid according to some embodiments.

### DETAILED DESCRIPTIONS

Aspects and features of the present disclosure, and a method of achieving the aspects and features will become apparent with reference to embodiments described later in detail together with the accompanying drawings. However, an embodiment of embodiments of the present disclosure are not necessarily limited to the embodiments as disclosed under, but may be implemented in various different forms. Thus, these embodiments are set forth to make the present disclosure complete, and to completely inform the scope of the present disclosure to those of ordinary skill in the technical field to which the present disclosure belongs.

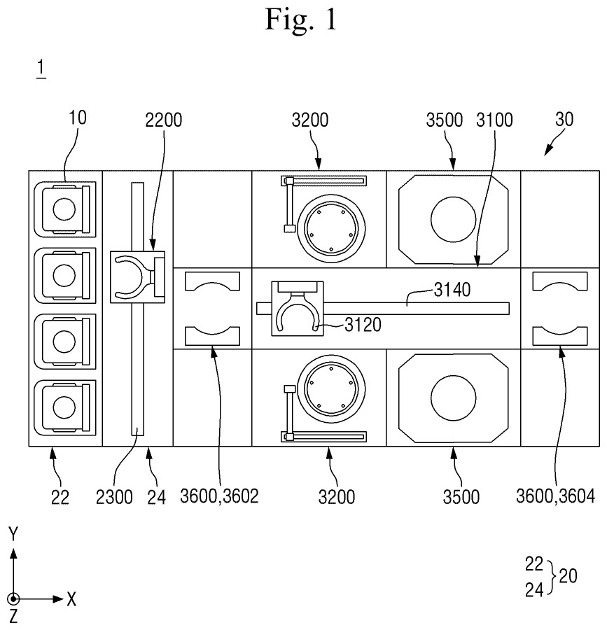

FIG. 1 is a plan view schematically showing a substrate treating apparatus according to some embodiments.

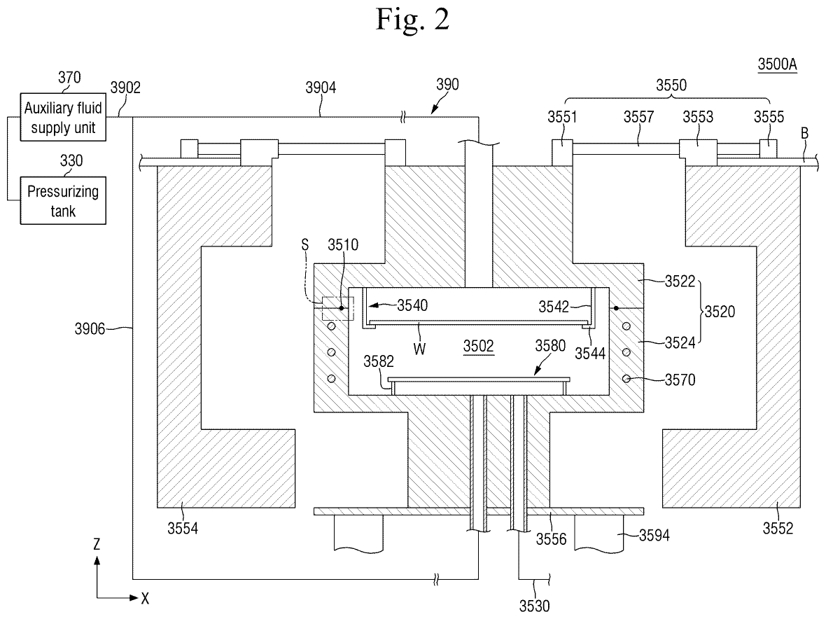

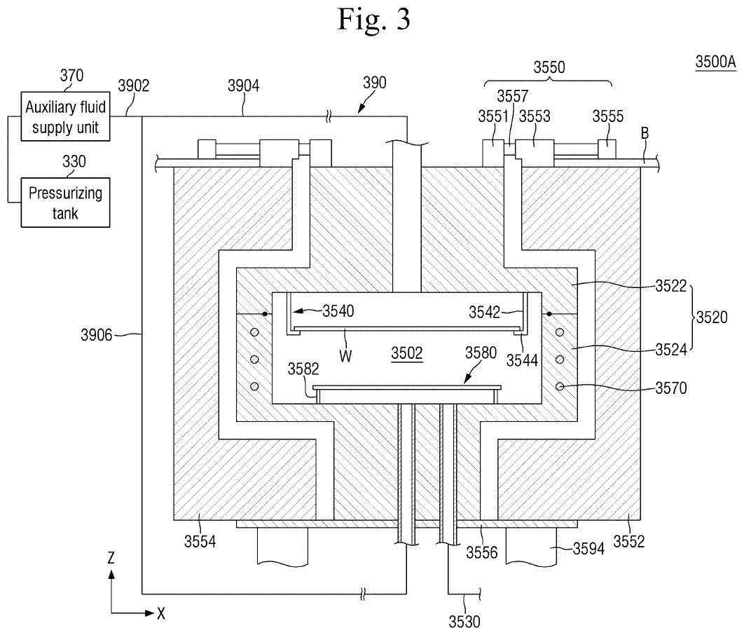

FIG. 2 and FIG. 3 are cross-sectional views schematically showing a substrate treating apparatus according to some embodiments.

Referring to FIG. 1, a substrate treating apparatus 1 may include an index module 20 and a treating module 30. In some embodiments, the index module 20 and the treating module 30 may be sequentially arranged in a line. Hereinafter, a direction in which the index module 20 and the treating module 30 are arranged is referred to as a first direction X, and a direction that intersects the first direction X in a plan view or a top view is referred to as a second direction Y. A direction that intersects both the first direction X and the second direction Y may be referred to as a third direction Z.

The index module 20 may transfer a substrate W from a container 10 in which the substrate W is stored to the treating module 30 and may store a treated substrate W into the container 10. The index module 20 may extend along the second direction Y. The index module 20 may include a load port 22 and an index frame 24. The load port 22 may be disposed at an opposite part of the substrate treating apparatus 1 from the treating module 30 in respect to the index frame 24. The container 10 containing the substrates W may be placed on the load port 22. A plurality of load ports 22 may be provided, wherein the plurality of load ports 22 may be arranged along the second direction Y.

The container 10 may be embodied as a sealed container such as a front open unified pod (FOUP). The container 10 may be placed onto the load port 22 by transfer means such as an overhead transfer, an overhead conveyor, or an automatic guided vehicle, or by an operator.

An index robot 2200 may be provided inside the index frame 24. A guide rail 2300 extending along the second direction Y may be provided in the index frame 24. The index robot 2200 may be movable on and along the guide rail 2300. The index robot 2200 may include a hand on which the substrate W is placed. The hand may be configured to move forward and backward, rotate about the third direction Z, and move along the third direction Z.

In some embodiments, the treating module 30 may perform a treating process on the substrate W. For example, the treating module 30 may perform a wet treating process or a supercritical fluid treating process on the substrate W.

The treating module 30 may include a treating block that performs a treating process on the substrate W. A plurality of treating blocks may be stacked on top of each other. Each treating block may include a transfer chamber 3100, a wet treating chamber 3200, a supercritical fluid treating chamber 3500, and a buffer chamber 3600.

The transfer chamber 3100 may transfer the substrate W between the wet treating chamber 3200 and the supercritical fluid treating chamber 3500 and within the treating module 30. The transfer chamber 3100 may extend parallel to the first direction X. For example, a side surface of the transfer chamber 3100 extending along the first direction X is longer than a side surface of the transfer chamber 3100 extending along the second direction Y. A transfer unit 3120 may be provided in the transfer chamber 3100. The transfer unit 3120 may transfer the substrate W between the wet treating chamber 3200 and the supercritical fluid treating chamber 3500.

For example, the transfer unit 3120 may have an arm on which the substrate W is placed The arm of the transfer unit 3120 may be configured to move forward and backward, rotate around the third direction Z, or move along the third direction Z. A guide rail 3140 extending parallel to the first direction X may be provided within the transfer chamber 3100. The transfer unit 3120 may be configured to be movable on and along the guide rail 3140.

The wet treating chamber 3200 according to some embodiments may perform a cleaning process and remove foreign substances on the substrate W, such as a silicon wafer. However, the wet treating chamber 3200 may not only perform a specific cleaning process, but also perform a substrate treating process using various chemicals. For example, the wet treating chamber 3200 may perform an etching process to etch a film on the substrate W and a cleaning process performed after the etching process, or may perform a strip process that removes the film or foreign substances on the substrate W and a cleaning process performed after the strip process.

The wet treating chamber 3200 may be disposed on each of both opposing sides of the transfer chamber 3100. For example, the wet treating chamber 3200 respectively disposed on one side and the other side of the transfer chamber 3100 may be arranged to be opposite to each other in respect to the transfer chamber 3100 in a plan view. A plurality of wet treatment chambers 3200 may be formed. The plurality of wet treating chambers 3200 may be stacked on top of each other. The wet treatment chambers 3200 may face each other while the transfer chamber 3100 is interposed therebetween. The wet treating chamber 3200 may be disposed between the index module 20 and the supercritical fluid treating chamber 3500. The number of the wet treating chambers 3200 may correspond to the number of the supercritical fluid treating chambers 3500. However, the technical idea of the present disclosure is not necessarily limited thereto and the number of the wet treating chambers and the number of the supercritical fluid treating chambers 3500 may vary based on a footprint, process efficiency, etc. of the apparatus.

The supercritical fluid treating chamber 3500 supplies supercritical fluid to the substrate W and treat the substrate W. For example, the supercritical fluid treating chamber 3500 may dry the substrate W by supplying the supercritical fluid to the substrate W. The supercritical fluid treating chamber 3500 may perform a drying process on the substrate W which has been treated in the wet treating chamber 3200. In this case, a developer or an organic solvent remaining on the substrate W may be dried in the supercritical fluid treating chamber 3500.

The supercritical fluid treating chamber 3500 may be disposed on each of both opposing sides of the transfer chamber 3100. A plurality of supercritical fluid treating chambers 3500 may be formed. The plurality of supercritical fluid treating chambers 3500 may be stacked on top of each other. The supercritical fluid treating chamber 3500 may be disposed adjacent to the wet treating chamber 3200. The supercritical fluid treating chambers 3500 respectively disposed on one side and the other side of the transfer chamber 3100 may be arranged to be opposite to each other in respect to the transfer chamber 3100 in a plan view. However, the technical idea of the present disclosure is not necessarily limited thereto, and the arrangement thereof may vary considering the footprint, process efficiency, etc. of the apparatus.

A plurality of buffer chambers 3600 may be provided. Some of the buffer chambers 3600 may be disposed between the index module 20 and the transfer chamber 3100. Hereinafter, each of the buffer chambers 3600 between the index module 20 and the transfer chamber 3100 is referred to as a front buffer 3602. A plurality of front buffers 3602 may be provided and may be stacked on top of each other along a vertical direction. A plurality of rear buffers 3604 of the buffer chambers 3600 may be disposed adjacent to the transfer chamber 3100. For example, the plurality of rear buffers 3604 of the buffer chambers 3600 may be disposed outside of the transfer chamber 3100 along the first direction X. The plurality of rear buffers 3604 may be provided and may be stacked on top of each other along the vertical direction. Each of the front buffers 3602 and the rear buffers 3604 may temporarily store therein a plurality of substrates W. The substrate W stored in the front buffer 3602 may be input thereto or taken out therefrom by the index robot 2200 and the transfer unit 3120. The substrate W stored in the rear buffer 3604 may be input thereto or taken out therefrom by the transfer unit 3120.

The substrate treating apparatus may further include a control unit that controls the transfer unit 3120. In some embodiments, the control unit may control the transfer unit 3120 so that the substrate W is brought into the wet treating chamber 3200 and then into the supercritical fluid treating chamber 3500. In the wet treating chamber 3200, the substrate W may be developed or cleaned. In the supercritical fluid treating chamber 3500, the developer or the organic solvent remaining on the substrate W may be removed.

Referring to FIG. 2 and FIG. 3, a supercritical fluid treating chamber 3500A may remove a treating substance on the substrate W using the supercritical fluid. The supercritical fluid treating chamber 3500A may include a body 3520, a substrate support unit 3540, a fluid supply unit, and a blocking plate 3580. The body 3520 may provide a substrate treating space 3502 where a drying process is performed.

The body 3520 may include an upper body 3522 and a lower body 3524. The upper body 3522 and the lower body 3524 may be coupled to each other and provide the substrate treating space 3502 as described above. The upper body 3522 may be disposed on top of the lower body 3524. A position of the upper body 3522 may be fixed, and the lower body 3524 may be raised and lowered by a vertically-moving unit.

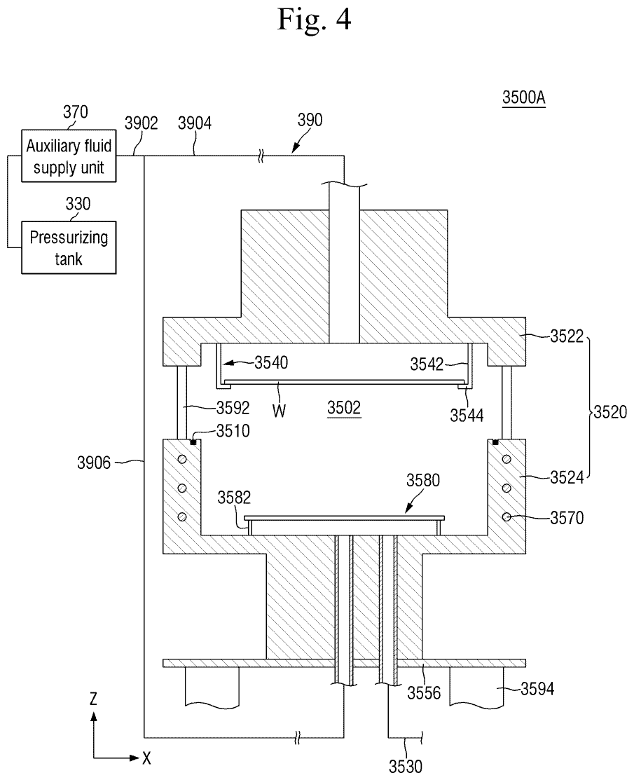

The vertically-moving unit may include a vertically-moving cylinder 3594 and a vertically-moving rod 3592 in FIG. 4. The vertically-moving cylinder 3594 may be connected to a vertically-moving plate 3556. The vertically-moving plate 3556 may be integrated with the lower body 3524. The vertically-moving rod 3592 may have one end inserted into the vertically-moving cylinder 3594, extends along the third direction Z, and may have the other end coupled to the upper body 3522.

When the vertically-moving cylinder 3594 vertically moves the vertically-moving plate 3556, the lower body 3524 may also move up or down together with the vertically-moving plate 3556. While the lower body 3524 is raised or lowered by the vertically-moving cylinder 3594, the vertically-moving rod 3592 may prevent the upper body 3522 and the lower body 3524 from moving along the first direction X. Accordingly, the vertically-moving rod 3592 may guide the vertical movement thereof to prevent the upper body 3522 and the lower body 3524 from leaving their correct positions.

Hereinafter, a position to which the lower body 3524 ascends and at which the lower body 3524 comes into contact with the upper body 3522 that defines the substrate treating space 3502 is referred to as a closed position. A position to which the lower body 3524 descends and at which the lower body 3524 is spaced apart from the upper body 3522 is referred to as an open position. For example, in FIG. 2 and FIG. 3, the body 3520 is at the closed position, and in FIG. 4, the body 3520 is at the open position.

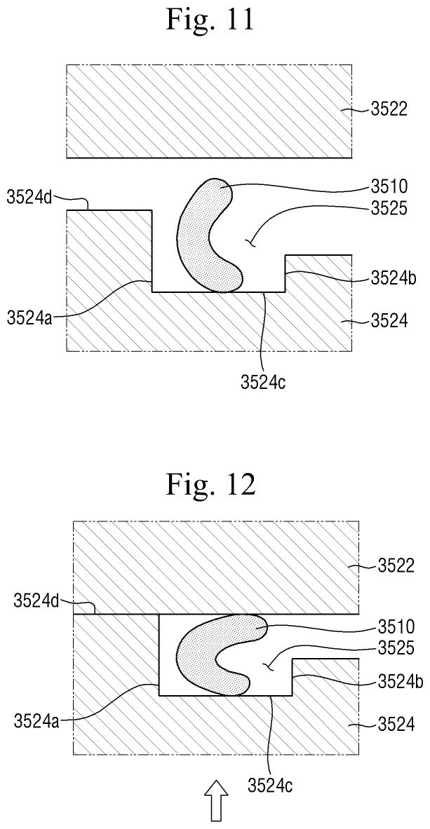

The lower body 3524 may include a sealing groove 3525 (refer to FIG. 11). A seal 3510 (refer to FIG. 11) may be inserted into the sealing groove 3525. For example, the seal 3510 may be in a form of an O-ring. During the process, the lower body 3524 may be in close contact with the upper body 3522 and maintain the closed position, thereby defining the substrate treating space 3502. However, even when the upper body 3522 and the lower body 3524 are at the closed position, a minute gap may be formed therebetween. The seal 3510 may seal the minute gap between the upper body 3522 and the lower body 3524, thereby blocking the substrate treating space 3502 from the outside. A detailed description of the seal 3510 will be described later.

A clamping unit may include a first clamping unit 3554 and a second clamping unit 3552. The first clamping unit 3554 and the second clamping unit 3552 disposed at opposite ends along the first direction X may clamp the body 3520. Inner side surfaces of the first clamping unit 3554 and the second clamping unit 3552 may include a clamping space into which both opposing sides of each of the upper body 3522 and the lower body 3524 are inserted. The first clamping unit 3554 and the second clamping unit 3552 may be movable under an operation of a moving unit 3550. A plurality of moving units 3550 may be provided. One of the moving units 3550 may be connected to the upper body 3522 and the first clamping unit 3554, and the other of the moving units 3550 may be connected to the upper body 3522 and the second clamping unit 3552.

The moving unit 3550 may include a first body 3551 coupled to the upper body 3522, a second body 3553 coupled to each of the first and second clamping units 3552 and 3554, and movable along a moving rail 3557, and a third body 3555 coupled to a fixed external wall B. Referring to FIG. 3, the second body 3553 may move along the fourth direction-X and may move the first and second clamping units 3554 and 3552 toward the body 3520.

The supercritical fluid treating chamber 3500A may further include a heater 3570. For example, the heater 3570 may be disposed inside a wall of the body 3520. The heater 3570 may heat the substrate treating space 3502 of the body 3520 so that the fluid supplied into an internal space of the body 3520 is maintained in a supercritical state.

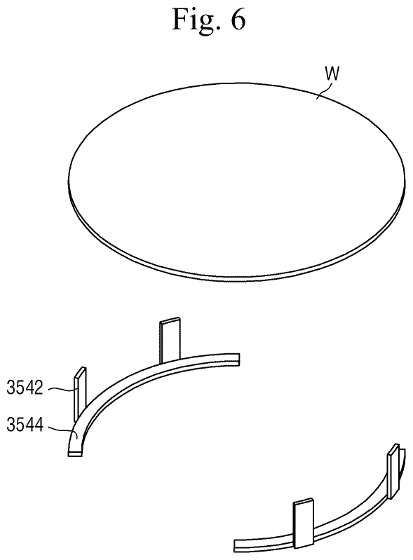

The substrate support unit 3540 may support the substrate W thereon and the substrate W within the substrate treating space 3502 of the body 3520. A detailed description of the substrate support unit 3540 will be described later with reference to FIG. 6.

The fluid supply unit may include a pressurizing tank 330, an auxiliary fluid supply unit 370, and a fluid supply line 390. The fluid supply unit may supply drying fluid to the substrate treating space 3502 of the body 3520. For example, the drying fluid in a supercritical state may be supplied to the substrate treating space 3502. In some embodiments, the drying fluid in a gaseous state may be supplied to the substrate treating space 3502 and may be transformed into the supercritical state within the substrate treating space 3502. The fluid may be, for example, carbon dioxide (CO₂). A specific configuration of the fluid supply unit will be described later.

The fluid supply line 390 may include a main supply line 3902, an upper branch line 3904, and a lower branch line 3906. The upper branch line 3904 and the lower branch line 3906 may stem from the main supply line 3902. The upper branch line 3904 may be coupled to the upper body 3522 and may supply the drying fluid from a position on top of the substrate W disposed on the substrate support unit 3540 to the substrate W. For example, the upper branch line 3904 may be coupled to a center of the upper body 3522. The lower branch line 3906 may be coupled to the lower body 3524 and may supply the drying fluid from a position under the substrate W disposed on the substrate support unit 3540 to the substrate W. For example, the lower branch line 3906 may be coupled to a center of the lower body 3524.

A discharge line 3530 may be connected to the lower body 3524. The supercritical fluid within the substrate treating space 3502 of the body 3520 may be discharged out of the body 3520 through the discharge line 3530.

The blocking plate 3580 may be disposed in the substrate treating space 3502 of the body 3520. The blocking plate 3580 may be provided in a disk shape. The disk shape refers to an object that is flat and round, resembling the shape of a disk or a circular plate. The blocking plate 3580 may be supported by a support 3582 so as to be spaced upward from a bottom of the body 3520. The support 3582 may be provided in a rod shape. A plurality of supports 3582 may be provided and spaced from each other by a certain distance. In a plan view, the blocking plate 3580 may overlap an outlet of the lower branch line 3906 and an inlet of the discharge line 3530. The blocking plate 3580 may prevent the drying fluid supplied through the lower branch line 3906 from being discharged directly toward the substrate W and thus prevent the substrate W from being damaged.

FIG. 4 is a cross-sectional view schematically showing a supercritical fluid treating chamber according to some embodiments.

Referring to FIG. 4, the position of the upper body 3522 may be fixed, and the lower body 3524 may descend along a length direction of the vertically-moving rod 3592 disposed under an operation of the vertically-moving cylinder 3594. When the lower body 3524 is spaced apart from the upper body 3522, the substrate treating space 3502 is opened, and at this time, the substrate W may be introduced thereto or taken out therefrom.

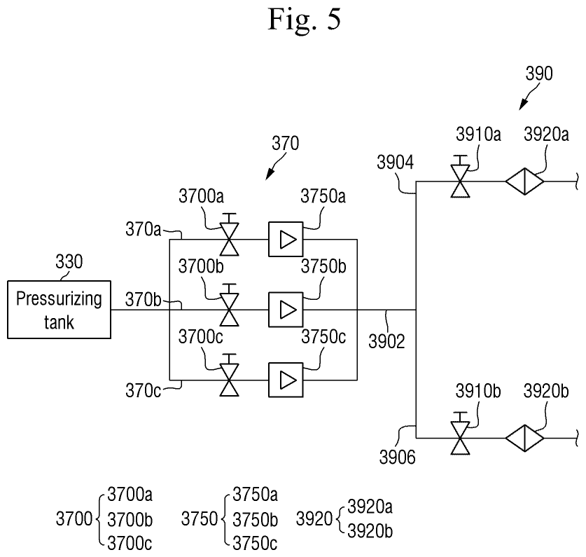

FIG. 5 is a diagram showing the fluid supply unit as shown in FIG. 2.

Referring to FIG. 5, the fluid supply unit may include the pressurizing tank 330, the auxiliary fluid supply unit 370, and the fluid supply line 390. The auxiliary fluid supply unit 370 may include a first auxiliary fluid supply unit 370a, a second auxiliary fluid supply unit 370b, and a third auxiliary fluid supply unit 370c.

The pressurizing tank 330 may store the fluid to be supplied to the substrate treating space 3502 and/or supply the fluid thereto. The fluid stored in the pressurizing tank 330 may be, for example, carbon dioxide (CO₂). The fluid supplied from the pressurizing tank 330 may be supplied to the substrate treating space 3502 along the auxiliary fluid supply unit 370 and the fluid supply line 390.

Each of the auxiliary fluid supply units 370 may include a control valve 3700 and a pump 3750. The control valve 3700 may be a valve that may be opened or closed and control flow of the fluid supplied to the substrate treating space 3502. The pump 3750 may control a flow rate of the fluid passing through the auxiliary fluid supply unit 370.

For example, the first auxiliary fluid supply unit 370a may include a first control valve 3700a and a first pump 3750a. The first auxiliary fluid supply unit 370a may control the fluid stored in the pressurizing tank 330 to flow at a relatively low flow rate. The second auxiliary fluid supply unit 370b may include a second control valve 3700b and a second pump 3750b. The second auxiliary fluid supply unit 370b may control the fluid stored in the pressurizing tank 330 to flow at a relatively high flow rate. The third auxiliary fluid supply unit 370c may include a third control valve 3700c and a third pump 3750c. The third auxiliary fluid supply unit 370c may control the fluid stored in the pressurizing tank 330 to flow at a relatively ultra-high flow rate.

FIG. 5 illustrates three control valves 3700 as being installed. However, an embodiment according to the present disclosure is not necessarily limited thereto. Hereinafter, the description will be made based on an example where the control valve 3700 includes the first control valve 3700a, the second control valve 3700b, and the third control valve 3700c as shown in FIG. 5.

The upper branch line 3904 may include an upper supply valve 3910a and a first filter 3920a. The lower branch line 3906 may include a lower supply valve 3910b and a second filter 3920b. Each of the upper supply valve 3910a and the lower supply valve 3910b can be opened or closed. Depending on the open or closed state of each of the upper supply valve 3910a and the lower supply valve 3910b, the fluid may selectively flow to the upper branch line 3904 or the lower branch line 3906.

A filter 3920 may remove impurities from the fluid. The filter 3920 may include the first filter 3920a and the second filter 3920b.

FIG. 6 is a perspective view showing the substrate support unit as shown in FIG. 2.

Referring to FIG. 6, the substrate support unit 3540 (refer to FIG. 2) may support the substrate W thereon so that a treatment target surface of the substrate W faces upwardly. The substrate support unit 3540 may include a fixing rod 3542 and a seat 3544. The fixing rod 3542 may be fixed to the upper body 3522 (refer to FIG. 2) so as to protrude downwardly from a bottom of the upper body 3522. The fixing rod 3542 may extend along the third direction Z. A plurality of fixing rods 3542 may be provided and may be spaced apart from each other. The fixing rods 3542 may be positioned so that the substrate W does not interfere with the fixing rods 3542 when the substrate W is put into or out of a space surrounded with the fixing rods.

The seat 3544 may be coupled to the fixing rods 3542. For example, the seat 3544 may be in contact with bottoms of the fixing rods 3542 and may extend along a portion of an outer circumference of the space surrounded with the fixing rods 3542. Due to this structure, an edge area of the substrate W introduced into the substrate treating space 3502 of the body 3520 may be placed on the seat 3544 such that an entire upper surface area of the substrate W, an inner area of a bottom of the substrate W, and a portion of an edge area of the bottom of the substrate W are exposed to the fluid supplied to the substrate treating space 3502.

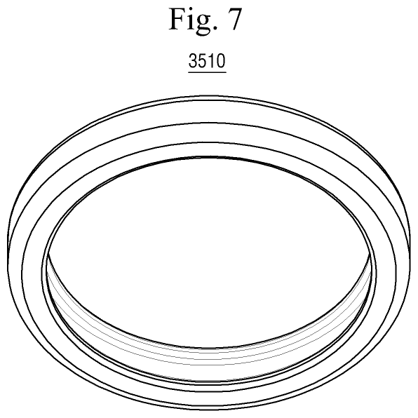

FIG. 7 is a perspective view showing the seal as shown in FIG. 2.

Referring to FIG. 2 and FIG. 7, in some embodiments, the seal 3510 may be provided in an annular ring shape that may be inserted into the sealing groove 3525.

In some embodiments, the seal 3510 may include a material having elasticity. Accordingly, the shape of the seal 3510 may vary depending on the pressure inside the substrate treating space 3502.

In some embodiments, a sealing force of the substrate treating space 3502 may be improved by deforming the seal 3510. A specific scheme for deforming the seal 3510 will be described later.

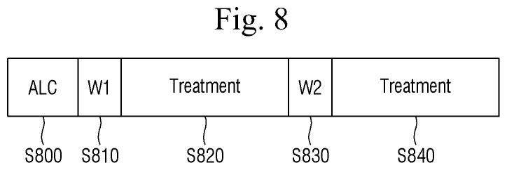

FIG. 8 is a diagram showing an operation sequence of the substrate treating apparatus according to some embodiments.

Referring to FIG. 8, as the number of substrates W accumulated increases, the seal 3510 may become loose such that the fluid within the substrate treating space 3502 may leak. To prevent this situation, the seal 3510 in the supercritical fluid treating chamber 3500A may be replaced at a regular interval. For example, the replacement may be performed every time a predefined number of substrates W accumulate therein.

When the predefined number of substrates W are cumulatively input to the supercritical fluid treating chamber 3500A, a replacement step of the seal 3510 including an automatic leak cleaning (ALC) step is performed in S800.

After replacing the seal 3510 with a new seal, a first substrate W1 is inserted into the chamber 3500A in S810. Afterwards, substrate treatment using the supercritical fluid is performed on the first substrate W1 introduced thereto in S820.

When the treatment of the first substrate W1 has been completed, a second substrate W2 is inserted thereto in S830. Then, substrate treatment using the supercritical fluid is performed on the second substrate W introduced thereto in S840.

FIG. 8 illustrates that the substrate treatment only on the first and second substrates W1 and W2 is performed after the replacement of the seal 3510. For example, the replacement may be performed every time the two substrates W1 and W2 are accumulated therein. However, an embodiment of the present disclosure is not necessarily limited thereto. The replacement may be performed every time at least three substrates W are accumulated therein.

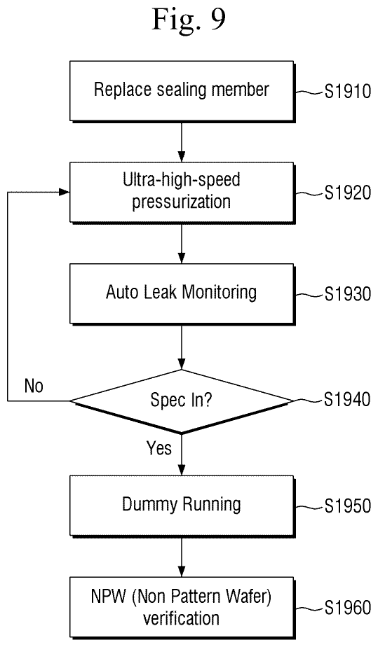

FIG. 9 is a flowchart for illustrating a replacement method of the seal.

Referring to FIG. 9, replacement of the seal 3510 may be performed in a following order. When the predefined number of substrates W are cumulatively added to the supercritical fluid treating chamber 3500A, the seal 3510 in the supercritical fluid treating chamber 3500A is replaced in S1910.

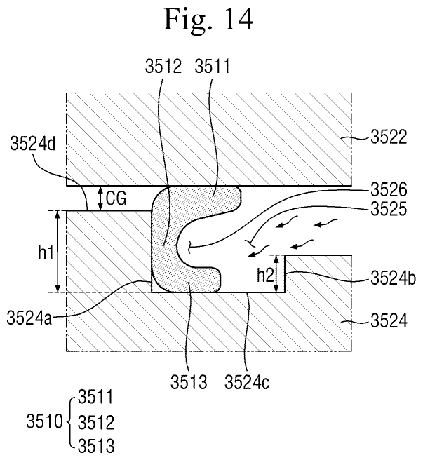

After replacing the seal 3510, ultra-high-speed pressurization is performed to ensure that the seal 3510 adheres well to a groove wall within the sealing groove 3525 (refer to FIG. 14) in S1920. A detailed description of the ultra-high-speed pressurization will be provided later.

After the ultra-high speed pressurizing step has been performed, an auto leak monitoring (ALM) step is performed in S1930. A combination of the ultra-high speed pressurizing step and the automatic leak monitoring step is referred to as the ALC (Auto Leak Clean) step.

After performing the automatic leakage monitoring, whether a specification is met is checked in S1940. For example, whether a fluid leakage amount is greater than or equal to a predefined reference is checked in S1940.

If the specification is met (Yes), a dummy running is performed in S1950. If the specification is not met (No), the sealing operation is performed again via the ultra-high-speed pressurization in S1920.

Afterwards, NPW (Non Pattern Wafer) verification is performed on the substrate W on which the dummy running has been performed in 1960.

When the method includes the automatic leak cleaning step, the supercritical fluid treating chamber 3500A may be sealed via the ultra-high-speed pressurization. Thus, a time required for the sealing operation may be shortened.

Furthermore, as the adhesion of the seal 3510 to the groove wall increases due to the ultra-high-speed pressurization, an interval at which the seal 3510 is replaced may increase.

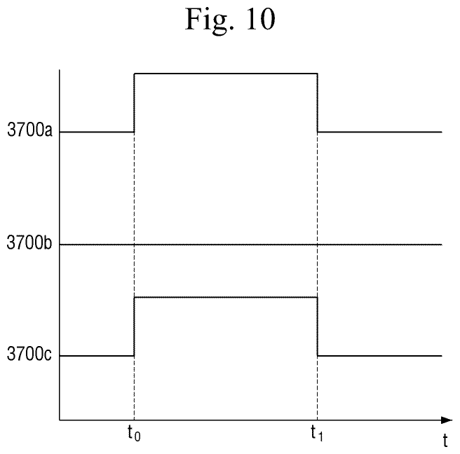

FIG. 10 is a diagram illustrating an operation of the fluid supply unit in FIG. 5 according to some embodiments.

Referring to FIG. 5 and FIG. 10, after replacing the seal 3510, the ultra-high-speed pressurization may be performed and seal the substrate treating space 3502 from the outside.

In some embodiments, the first auxiliary fluid supply unit 370a which controls the fluid to flow at a relatively low flow rate, and the third auxiliary fluid supply unit 370c which controls the fluid to flow at a relatively ultra-high flow rate may be simultaneously opened.

For example, a controller controlling each of the control valves 3700 may simultaneously open the first control valve 3700a and the third control valve 3700c at a first time t0.

When a pressure in the substrate treating space 3502 reaches a target pressure, the first control valve 3700a and the third control valve 3700c may be closed at the same time.

For example, the controller controlling each of the control valves 3700 may simultaneously close the first control valve 3700a and the third control valve 3700c at a second time t1.

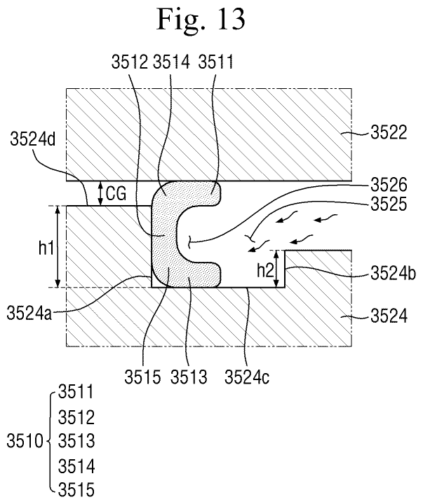

When the low-flow rate valve and the ultra-high-flow rate valve are opened simultaneously, the substrate treating space 3502 may quickly change to the supercritical state. Furthermore, the pressure caused by the fluid injected into the substrate treating space 3502 through the first control valve 3700a and the third control valve 3700c may cause deformation of the seal 3510 and define a tube space (3526 in FIG. 13). The substrate treating space 3502 may be sealed from the outside by the deformed seal 3510.

FIGS. 11 to 13 are enlarged views of a S area of FIG. 2.

Referring to FIG. 11, in some embodiments, the lower body 3524 may include the sealing groove 3525. The sealing groove 3525 may be defined in an upper surface of the lower body 3524. The sealing groove 3525 may include a first inner wall 3524a, a second inner wall 3524b, and a groove surface 3524c.

The first inner wall 3524a and the second inner wall 3524b may face each other while the groove surface 3524c is disposed therebetween. A height of the first inner wall 3524a may be greater than a height of the second inner wall 3524b. For example, h1 may be greater than h2.

When the upper body 3522 and the lower body 3524 are at the open position, the seal 3510 may be installed in the sealing groove 3525.

Referring to FIG. 12, the lower body 3524 may be raised or lowered under the operation of the vertically-moving cylinder 3594. When the lower body 3524 moves up, the upper body 3522 and an outer upper surface 3524d of the lower body 3524 may come into contact with each other. When the upper body 3522 and lower body 3524 come into contact with each other, a position thereof may correspond to the closed position.

Referring to FIG. 10 and FIG. 13, when the body 3520 is at the closed position, the controller controlling each of the control valve 3700 may open the first control valve 3700a and the third control valve 3700c simultaneously at the first time t0 such that the fluid is inserted into the substrate treating space 3502.

The fluid injected into the substrate treating space 3502 may be injected into the sealing groove 3525 and pressurize the seal 3510. Due to the pressure of the fluid, the seal 3510 may move within the sealing groove 3525 toward the outside of the chamber, such that the seal 3510 may be deformed.

The seal 3510 may include a first sealing portion 3511, a second sealing portion 3512, a third sealing portion 3513, a first curved portion 3514, and a second curved portion 3515 at least partially surrounding the tube space 3526. As used herein, the phrase “at least partially surround” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element. The first curved portion 3514 may include a curved surface formed between the first sealing portion 3511 and the second sealing portion 3512. Additionally, the second curved portion 3515 may include a curved surface formed between the second sealing portion 3512 and the third sealing portion 3513.

The first sealing portion 3511 may contact the lower surface of the upper body 3522. The second sealing portion 3512 may contact the first inner wall 3524a. The third sealing portion 3513 may contact the groove surface 3524c of the sealing groove 3525. More specifically, the seal 3510 may be deformed into a shape surrounding a space defined by the upper body 3522 and the sealing groove 3525 under the pressure of the fluid. For example, the seal 3510 may be deformed into a C-shape including a deep tube space 3526.

Furthermore, the seal 3510 may be deformed into a shape corresponding to the space defined by the upper body 3522 and the sealing groove 3525 under the high-flow rate pressure. For example, the seal 3510 may be deformed such that the first sealing portion 3511, the second sealing portion 3512, and the third sealing portion 3513 may be in close contact with a lower surface of the upper body 3522, the first inner wall 3524a, and the groove surface 3524c of the sealing groove 3525, respectively.

The deformed seal 3510 may include the tube space 3526. As the tube space 3526 is formed, a chamber gap CG may be formed between the upper body 3522 and the lower body 3524. For example, the chamber gap CG may be formed between the lower surface of the upper body 3522 and the outer upper surface 3524d of the lower body 3524. The outer upper surface 3524d of the lower body 3524 may extend from one end of the first inner wall 3524a. The first curved portion 3514 may seal the substrate treating space 3502 from the outside communicating with the chamber gap CG.

According to some embodiments, the substrate treating space 3502 may be sealed by deforming the seal 3510 under the ultra-high-flow rate pressure. Thus, the time required for the sealing operation may be shortened.

Furthermore, the seal 3510 may be deformed into a shape corresponding to a shape of the sealing groove 3525 under the ultra-high-speed pressurization, thereby improving the sealing power of the seal 3510. Accordingly, the interval at which the seal 3510 is replaced may increase.

FIG. 14 is a cross-sectional view showing a seal according to some embodiments.

Referring to FIG. 14, in some embodiments, the seal 3510 may be deformed into an irregular shape under the ultra-high-speed pressurization.

For example, the seal 3510 may include the tube space 3526. The seal 3510 may be deformed into a shape corresponding to the space defined by the upper body 3522 and the sealing groove 3525. For example, the seal 3510 may be deformed such that the first sealing portion 3511, the second sealing portion 3512, and the third sealing portion 3513 may be in close contact with the lower surface of the upper body 3522, the first inner wall 3524a, and the groove surface 3524c of the sealing groove 3525, respectively.

However, the deformed shape thereof is not necessarily limited to the shape shown in the drawings. The seal 3510 may be deformed into various shapes such that a length and a thickness of each of the first sealing portion 3511 and the third sealing portion 3513 vary.

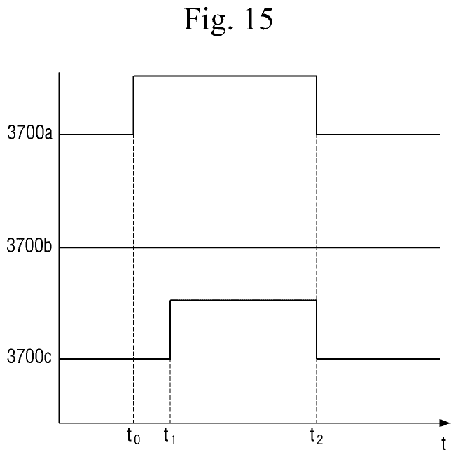

FIGS. 15 to 18 are diagrams for illustrating an operation of the fluid supply unit in FIG. 5 according to some embodiments. FIGS. 15 to 18 are diagrams corresponding to FIG. 10. To the extent that an element has not been described in detail, it may be assumed that the element is at least similar to corresponding elements that have been described in FIG. 10

Referring to FIG. 5 and FIG. 15, in some embodiments, after replacing the seal 3510, the first control valve 3700a that controls the fluid to flow at a relatively low flow rate may be opened, and then, the third control valve 3700c which controls the fluid to flow at relatively ultra-high flow rate may be opened.

For example, the controller that controls each of the control valves 3700 may open the first control valve 3700a at a first time t0 and may open the third control valve 3700c at a second time t1.

When the pressure in the substrate treating space 3502 reaches the target pressure, the controller may close the first control valve 3700a and the third control valve 3700c at the same time.

For example, the controller controlling each of the control valves 3700 may simultaneously close the first control valve 3700a and the third control valve 3700c at a third time t2.

In this way, a time interval t1 to t2 for which the low-flow rate valve and the ultra-high-flow rate valve are opened simultaneously may coincide with a valve operation timing. Thus, the substrate treating space 3502 may quickly change to a supercritical state. Furthermore, the pressure caused by the fluid injected into the substrate treating space 3502 through the first control valve 3700a and the third control valve 3700c may cause deformation of the seal 3510, thereby defining the tube space 3526. The substrate treating space 3502 may be sealed from the outside due to the deformed seal 3510.

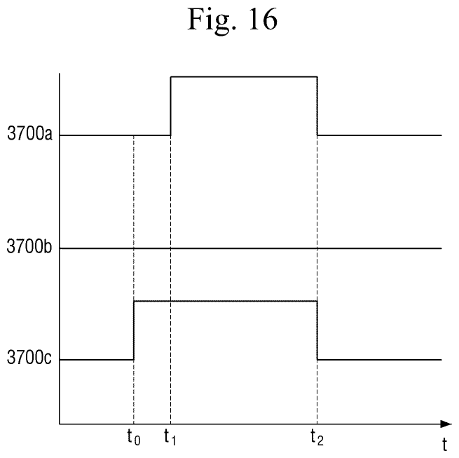

Referring to FIG. 5 and FIG. 16, in some embodiments, after replacing the seal 3510, the third control valve 3700c may be opened, and then, the first control valve 3700a may be opened.

For example, the controller that controls each of the control valves 3700 may open the third control valve 3700c at a first time t0 and may open the first control valve 3700a at a second time t1.

Then, when the pressure in the substrate treating space 3502 reaches the target pressure, the first control valve 3700a and the third control valve 3700c may be closed at the same time.

For example, the controller controlling each of the control valves 3700 may simultaneously close the first control valve 3700a and the third control valve 3700c at a third time t2.

In this way, a time interval t1 to t2 for which the low-flow rate valve and the ultra-high-flow rate valve are opened simultaneously may coincide with a valve operation timing. Thus, the substrate treating space 3502 may quickly change to a supercritical state. Furthermore, the pressure caused by the fluid injected into the substrate treating space 3502 through the first control valve 3700a and the third control valve 3700c may cause deformation of the seal 3510, thereby defining the tube space 3526. The substrate treating space 3502 may be sealed from the outside due to the deformed seal 3510.

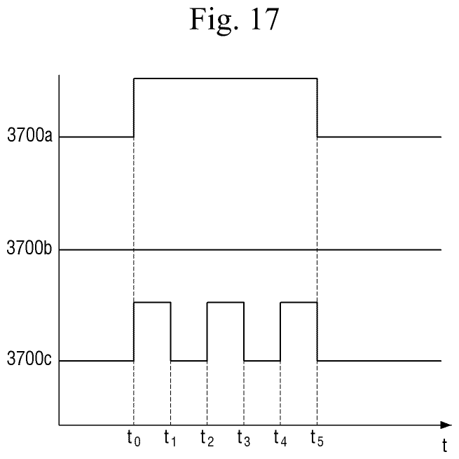

Referring to FIG. 5 and FIG. 17, in some embodiments, after replacing the seal 3510, the first control valve 3700a may be opened, and then, opening and closing of the third control valve 3700c may be repeated.

For example, the controller controlling each of the control valves 3700 may open the first control valve 3700a at a first time t0. Then, the controller may open the third control valve 3700c for a time interval from a first time t0 to a second time t1, for a time interval from a third time t2 to a fourth time t3, and for a time interval from a fifth time t4 to a sixth time t5 and may close the third control valve 3700c for a time interval from the second time t1 to the third time t2, and for a time interval from the fourth time t3 to the fifth time t4.

Then, when the pressure in the substrate treating space 3502 reaches the target pressure, both the first control valve 3700a and the third control valve 3700c may be closed.

For example, the controller controlling each of the control valves 3700 may close the first control valve 3700a and the third control valve 3700c at the sixth time t5.

In this way, time intervals t0 to t1, t2 to t3, and t4 to t5 for which the low-flow rate valve and the ultra-high-flow rate valve are opened simultaneously may coincide with a valve operation timing. Thus, the substrate treating space 3502 may quickly change to a supercritical state. Furthermore, the pressure caused by the fluid injected into the substrate treating space 3502 through the first control valve 3700a and the third control valve 3700c may cause deformation of the seal 3510, thereby defining the tube space 3526. The substrate treating space 3502 may be scaled from the outside due to the deformed seal 3510.

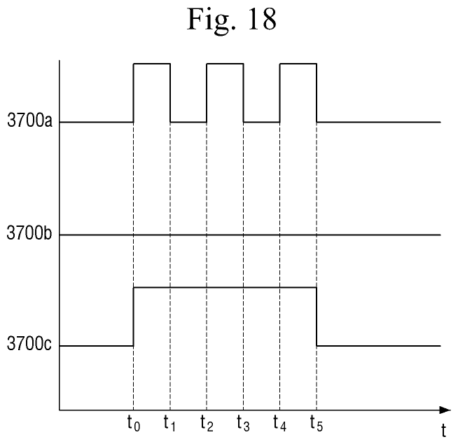

Referring to FIG. 5 and FIG. 18, in some embodiments, after replacing the seal 3510, the third control valve 3700c may be opened and then, opening and closing of the first control valve 3700a may be repeated.

For example, the controller controlling each of the control valves 3700 may open the third control valve 3700c at the first time t0. Then, the controller may open the first control valve 3700a for a time interval from a first time t0 to a second time t1, for a time interval from a third time t2 to a fourth time t3, and for a time interval from a fifth time t4 to a sixth time t5 and may close the first control valve 3700a for a time interval from the second time t1 to the third time t2, and for a time interval from the fourth time t3 to the fifth time t4.

Then, when the pressure in the substrate treating space 3502 reaches the target pressure, both the first control valve 3700a and the third control valve 3700c may be closed.

For example, the controller controlling each of the control valves 3700 may close the first control valve 3700a and the third control valve 3700c at the sixth time t5.

In this way, time intervals t0 to t1, t2 to t3, and t4 to t5 for which the low-flow rate valve and the ultra-high-flow rate valve are opened simultaneously may coincide with a valve operation timing. Thus, the substrate treating space 3502 may quickly change to a supercritical state. Furthermore, the pressure caused by the fluid injected into the substrate treating space 3502 through the first control valve 3700a and the third control valve 3700c may cause deformation of the seal 3510, thereby defining the tube space 3526. The substrate treating space 3502 may be sealed from the outside due to the deformed seal 3510.

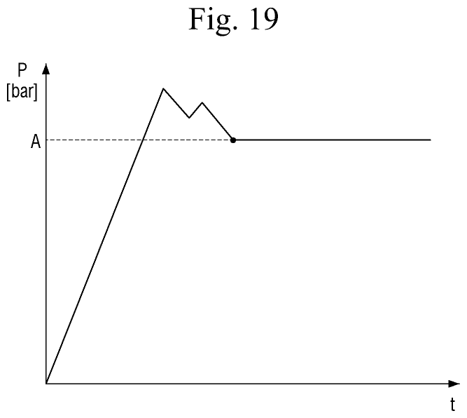

FIG. 19 is a diagram illustrating example pressure change inside a chamber while performing an operation using the supercritical fluid according to some embodiments.

Referring to FIG. 19, a x-axis represents a time and a y-axis represents a pressure.

Referring to FIG. 2, FIG. 5, FIG. 8, and FIG. 19, in order to perform substrate treatment using the supercritical fluid on the substrate W disposed in the supercritical fluid treating chamber 3500A in S820 or S840, the pressure in the substrate treating space 3502 may be used to maintain a constant process pressure A.

For this purpose, the process pressure A may be maintained by opening a selected one of the first control valve 3700a that supplies relatively low-pressure fluid, the second control valve 3700b that supplies relatively high-pressure fluid, and the third control valve 3700c that supplies relatively ultra-high-pressure fluid.

When the pressure within the substrate treating space 3502 reaches the target process pressure A, the process on the substrate W may be performed while maintaining the pressure within the substrate treating space 3502 at the process pressure A.

Although embodiments of the present disclosure have been described with reference to the accompanying drawings, embodiments of the present disclosure are not necessarily limited to the above embodiments and may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A substrate treatment apparatus, comprising:
an upper body;
a lower body coupled to the upper body and defining a substrate treating space therebetween;
a seal disposed between the upper body and the lower body, wherein the seal seals the substrate treating space from an outside;
a fluid supply unit configured to supply fluid to the substrate treating space; and
a controller,
wherein the fluid supply unit includes:
a first auxiliary fluid supply unit configured to control the fluid to flow at a first flow rate; and
a second auxiliary fluid supply unit configured to the fluid to flow at a second flow rate different from the first flow rate, and
wherein the controller is configured to control the first auxiliary fluid supply unit and the second auxiliary fluid supply unit such that the fluid flows into the substrate treatment space through the first auxiliary fluid supply unit and the second auxiliary fluid supply unit in an ultra-high-speed pressurizing step, during at least one time interval.

2. The substrate treatment apparatus of claim 1, wherein the fluid supply unit further includes a fluid supply line configured to introduce the fluid into the substrate treating space,
wherein each of the first auxiliary fluid supply unit and the second auxiliary fluid supply unit is directly connected to a pressurizing tank and the fluid supply line.

3. The substrate treatment apparatus of claim 1, wherein in the ultra-high-speed pressurizing step, the controller is configured to:
open the first auxiliary fluid supply unit; and
open the second auxiliary fluid supply unit such that the fluid flows into the substrate treating space through the first auxiliary fluid supply unit and the second auxiliary fluid supply unit after a first time elapses.

4. The substrate treatment apparatus of claim 1, wherein in the ultra-high-speed pressurizing step, the controller is configured to:
open the first auxiliary fluid supply unit for a second time; and
repeat opening and closing of the second auxiliary fluid supply unit at least twice for the second time.

5. The substrate treatment apparatus of claim 1, wherein the lower body has a sealing groove defined therein,
wherein the sealing groove has a first inner wall, a second inner wall, and a groove surface,
wherein the first inner wall and the second inner wall face each other while the groove surface is interposed therebetween,
wherein the seal includes a first sealing portion, a second sealing portion, and a third sealing portion,
wherein the first sealing portion contacts a lower surface of the upper body,
wherein the second sealing portion contacts the first inner wall, and
wherein the third sealing portion contacts the groove surface.

6. The substrate treatment apparatus of claim 5, wherein the seal further includes a tube space, wherein the tube space is at least partially surrounded by the first sealing portion, the second sealing portion, and/or the third sealing portion.

7. The substrate treatment apparatus of claim 6, wherein a cross section of the seal perpendicular to a plan view thereof has a C shape.

8. The substrate treatment apparatus of claim 5, wherein a dimension from the groove surface to the upper body is greater than a height of the first inner wall.

9. The substrate treatment apparatus of claim 8, wherein the first sealing portion allows a chamber gap to be defined between the upper body and an outer upper surface of the lower body extending from one end of the first inner wall,
wherein the seal further includes:
a first curved portion between the first sealing portion and the second sealing portion; and
a second curved portion between the second sealing portion and the third sealing portion, and
wherein the substrate treating space is sealed from the chamber gap by the first curved portion.

10. The substrate treatment apparatus of claim 1, wherein the seal is elastic.

11. The substrate treatment apparatus of claim 1, wherein the fluid is or includes carbon dioxide.

12. The substrate treatment apparatus of claim 1, wherein the substrate treating apparatus further comprises a clamping unit,
wherein the clamping unit includes a clamping space into which both opposing side surfaces of each of the upper body and the lower body are inserted.

13. A substrate treatment method, comprising:
moving a lower body so as to contact the upper body under an operation of a cylinder to define a substrate treating space therebetween;
inserting both opposing side surfaces of each of the upper body and the lower body into a clamping space of a clamping unit and fixing the upper body and the lower body using the clamping unit; and
performing an ultra-high speed pressurizing step in which both a first auxiliary fluid supply unit and a second auxiliary fluid supply unit are opened so that fluid flows into the substrate treating space, wherein each of the first auxiliary fluid supply unit and the second auxiliary fluid supply unit is connected to the upper body and the lower body, wherein the second auxiliary fluid supply unit controls the fluid to flow at a higher flow rate than a flow rate at which the first auxiliary fluid supply unit controls the fluid to flow, and
wherein a pressure of the fluid flowing into the substrate treating space acts on the seal to deform a contact surface of the seal subjected to the pressure such that the substrate treating space is sealed from an outside by the deformed seal.

14. The substrate treatment method of claim 13, wherein in the ultra-high-speed pressurizing step,
wherein the first auxiliary fluid supply unit is opened, and, after a first time elapses, the second auxiliary fluid supply unit is opened such that the fluid flows into the substrate treating space through the first auxiliary fluid supply unit and the second auxiliary fluid supply unit.

15. The substrate treatment method of claim 13, wherein in the ultra-high-speed pressurizing step, the first auxiliary fluid supply unit is opened for a second time, and opening and closing of the second auxiliary fluid supply unit is repeated at least twice for the second time.

16. The substrate treatment method of claim 13, wherein the contact surface of the seal is deformed to define a tube space in a middle area thereof,
wherein the seal includes a first sealing portion, a second sealing portion, and a third sealing portion surrounding the tube space,
wherein the lower body has a sealing groove defined therein,
wherein the sealing groove includes a first inner wall, a second inner wall, and a groove surface,
wherein the first inner wall and the second inner wall face each other while the groove surface is interposed therebetween,
wherein the first sealing portion is in contact with a lower surface of the upper body,
wherein the second sealing portion is in contact with the first inner wall, and
wherein a third sealing portion is in contact with the groove surface.

17. The substrate treatment method of claim 16, wherein the first sealing portion allows a chamber gap to be defined between the upper body and an outer upper surface of the lower body extending from one end of the first inner wall.

18. The substrate treatment method of claim 17, wherein the seal further includes:
a first curved portion between the first sealing portion and the second sealing portion; and
a second curved portion between the second sealing portion and the third sealing portion,
wherein the substrate treating space is sealed from the chamber gap by the first curved portion.

19. The substrate treatment method of claim 13, wherein the fluid is carbon dioxide.

20. A substrate treatment apparatus, comprising:
an upper body;
a lower body coupled to the upper body to define a substrate treating space therebetween;
a seal disposed between the upper body and the lower body and sealing the substrate treating space from an outside;
a fluid supply unit configured to supply fluid to the substrate treating space;
a clamping unit including a clamping space into which both opposing side surfaces of each of the upper body and the lower body are inserted; and
a controller,
wherein the fluid supply unit includes:
a first auxiliary fluid supply unit configured to control the fluid to flow at a first flow rate; and
a second auxiliary fluid supply unit configured to the fluid to flow at a second flow rate different from the first flow rate, and
wherein in an ultra-high-speed pressurizing step, the controller is configured to open the first auxiliary fluid supply unit, and the controller is configured to open the second auxiliary fluid supply unit so that the fluid flows into the substrate treating space through the first auxiliary fluid supply unit and the second auxiliary fluid supply unit after a first time elapses.
